(19) United States
(12) Patent Application Publication
(10) Pub. No.: US 2026/0206194 A1
(43) Pub. Date: Jul. 16, 2026

(54) HEAT EXCHANGERS FOR SEMICONDUCTOR DEVICE ASSEMBLIES

(71) Applicant: SEMICONDUCTOR COMPONENTS INDUSTRIES, LLC, Scottsdale, AZ (US)

(72) Inventors: Jinseok RYU, Incheon (KR); Dongwook KANG, Bucheon (KR); Sangyun MA, Bucheon (KR); Jonghwan BAEK, Seoul (KR)

(73) Assignee: SEMICONDUCTOR COMPONENTS INDUSTRIES, LLC, Scottsdale, AZ (US)

(21) Appl. No.: 19/408,216

(22) Filed: Dec. 3, 2025

Related U.S. Application Data
(60) Provisional application No. 63/746,022, filed on Jan. 16, 2025.

(51) Int. Cl. H05K 7/20

(52) U.S. Cl. CPC H05K 7/20927

(57) ABSTRACT

A power electronics assembly may include a power device module. A power electronics assembly may include a heat exchanger that includes a baseplate having a top side and a bottom side, a plurality of fins extending from the bottom side of the baseplate, and a housing. The heat exchanger may include a bypass that allows a portion of a working fluid to bypass one or more of the plurality of fins.

### CROSS-REFERENCE TO RELATED APPLICATION

This application claims the benefit of and priority to U.S. Provisional Application No. 63/746,022, filed Jan. 16, 2025, which is incorporated by reference herein in its entirety.

### TECHNICAL FIELD

This description relates to semiconductor device assemblies. More specifically, this description relates to heat exchangers for dissipating heat from power device modules of semiconductor device assemblies.

### BACKGROUND

Semiconductor device assemblies, such as assemblies including power semiconductor devices (which can be referred to as power modules, multi-chip power modules, etc.), can be implemented using semiconductor die, substrates (e.g., direct-bonded metal substrates, ceramic substrates, and so forth), wire bonds, etc. Such semiconductor device assemblies can be coupled with one or more heat exchangers for dissipating heat generated by the semiconductor devices during operation.

### SUMMARY

In some aspects, the techniques described herein relate to a power electronics assembly, including: a power device module; and a heat exchanger that includes: a baseplate having a top side and a bottom side; a plurality of fins extending from the bottom side of the baseplate; and a housing, the housing and the baseplate defining an interior volume and the plurality of fins located in the interior volume; wherein the heat exchanger includes a bypass that allows a portion of a working fluid to bypass one or more of the plurality of fins.

In some aspects, the techniques described herein relate to a power electronics assembly, wherein the bypass is a bottom bypass extending between a bottom end of at least one of the plurality of fins and a wall of the housing.

In some aspects, the techniques described herein relate to a power electronics assembly, wherein the bottom bypass includes: a first height in a first region of the heat exchanger extending between a first fin of the plurality of fins and a first portion of the wall; and a second height in a second region of the heat exchanger extending between a second fin of the plurality of fins and a second portion of the wall; wherein the first height is different than the second height.

In some aspects, the techniques described herein relate to a power electronics assembly, wherein a length of the first fin is different than a length of the second fin.

In some aspects, the techniques described herein relate to a power electronics assembly, wherein a thickness of the first portion of the wall is different than a thickness of the second portion of the wall.

In some aspects, the techniques described herein relate to a power electronics assembly, wherein the bypass is a side bypass extending in a direction transverse to a longitudinal axis of a first fin of the plurality of fins between a side of the first fin and a wall of the housing.

In some aspects, the techniques described herein relate to a power electronics assembly, wherein a width of the side bypass is greater than a spacing between adjacent ones of the plurality of fins.

In some aspects, the techniques described herein relate to a power electronics assembly, wherein a size of the side bypass is different between a first region of the heat exchanger and a second region of the heat exchanger.

In some aspects, the techniques described herein relate to a power electronics assembly, wherein the side bypass in the first region is defined at least in part by a first portion of the wall of the housing and the first fin and the side bypass in the second region is defined at least in part by a second portion of the wall and a second fin of the plurality of fins, wherein a shape or a thickness of the first fin or the first portion of the wall is different than a shape or a thickness of the second fin or the second portion of the wall.

In some aspects, the techniques described herein relate to a power electronics assembly, wherein the bypass includes a first portion having a first size and a second portion having a second size that is different than the first size.

In some aspects, the techniques described herein relate to a power electronics assembly, including: a power device module; and a heat exchanger that includes: a baseplate having a top side and a bottom side; a plurality of fins extending from the bottom side of the baseplate; and a housing, wherein the housing and the baseplate define an interior volume, the plurality of fins located in the interior volume; wherein the heat exchanger includes a first region and a second region and at least one of a fin-to-fin spacing, a length of at least one of the plurality of fins, or a thermal conductivity of at least one of the plurality of fins is different between the first region and the second region.

In some aspects, the techniques described herein relate to a power electronics assembly, wherein the power device module includes a first portion aligned with the first region of the heat exchanger that has a first heat generation and a second portion aligned with the second region of the heat exchanger that has a second heat generation that is different than the first heat generation.

In some aspects, the techniques described herein relate to a power electronics assembly, wherein the heat exchanger includes a bypass that allows a portion of a working fluid to bypass one or more of the plurality of fins, the bypass including a first portion in the first region that has a first size and a second portion in the second region that has a second size that is different than the first size.

In some aspects, the techniques described herein relate to a power electronics assembly, wherein the first portion of the bypass extends between a first fin of the plurality of fins and a first portion of a wall of the housing and the second portion of the bypass extends between a second fin of the plurality of fins and a second portion of the wall of the housing, wherein a length of the first fin is different than a length of the second fin or a thickness of the first portion of the wall is different than a thickness of the second portion of the wall.

In some aspects, the techniques described herein relate to a power electronics assembly, wherein the bypass is a bottom bypass extending between bottom ends of the plurality of fins and the wall of the housing, wherein the heat exchanger includes a third region that does not include a bypass.

In some aspects, the techniques described herein relate to a power electronics assembly, wherein the third region is located downstream in a fluid flow direction of the first region and the second region.

In some aspects, the techniques described herein relate to a power electronics assembly, wherein the third region is located between the first region and the second region.

In some aspects, the techniques described herein relate to a power electronics assembly, wherein the power device module is a first power device module disposed in a first casing, the power electronics assembly further including a second power device module disposed in a second casing, wherein the first power device module and the second power device module are aligned with the first region and the second region is aligned with a space between the first casing and the second casing.

In some aspects, the techniques described herein relate to a power electronics assembly, wherein the second region of the heat exchanger includes a bypass that allows a portion of a working fluid to bypass one or more of the plurality of fins.

In some aspects, the techniques described herein relate to a power electronics assembly, wherein the first region of the heat exchanger does not include a bypass.

In some aspects, the techniques described herein relate to a method of manufacturing a power electronics assembly, the method including: receiving a heat exchanger that includes: a baseplate having a top side and a bottom side; a plurality of fins extending from the bottom side of the baseplate; and a housing, wherein the housing and the baseplate define an interior volume, the plurality of fins located in the interior volume; wherein the heat exchanger includes a first region and a second region and at least one of a fin-to-fin spacing, a length of at least one of the plurality of fins, or a thermal conductivity of at least one of the plurality of fins is different between the first region and the second region; and coupling a power device module to the baseplate.

### BRIEF DESCRIPTION OF THE DRAWINGS

FIG. 1A is a schematic side view of an example power electronics assembly;

FIG. 1B is a schematic side view of an example power electronics assembly that includes two power device modules coupled to a heat exchanger.

FIG. 1C is a top view of the heat exchanger of FIG. 1B.

FIGS. 1D-1F are top views of examples of heat exchangers with different configurations of regions of the heat exchangers.

FIG. 2 is a schematic cross-sectional side view of an example heat exchanger.

FIGS. 3A-3D are cross sectional side views of example heat sinks with varying fin configurations.

FIG. 4 is a cross-sectional side view of an example heat exchanger in the form of a liquid cooling jacket heat exchanger.

FIGS. 5A-5D are cross-sectional side views of example heat exchangers with varying pin and housing configurations.

FIG. 6 is a schematic of a heat exchanger.

FIG. 7 is a flowchart of an example method of manufacturing a power electronics assembly.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated.

### DETAILED DESCRIPTION

Semiconductor device assemblies for use in power electronics generate a significant amount of heat during operation of the devices. The heat generated by the devices is dissipated by one or more heat exchangers so that operating temperatures of the semiconductor devices remain below allowable temperature limits. In some implementations, multiple semiconductor device assemblies may be coupled to the same heat exchanger. For example, two or three or more semiconductor power device modules may be coupled to the same heat exchanger along a length of the heat exchanger. The increasing number of power modules can create a technical problem of a variation along a length of the heat exchanger that can result in inconsistent heat dissipation from the multiple power modules, inconsistent operating temperatures of the semiconductor devices in the power modules, and unstable or inconsistent working fluid pressure drops across the heat exchanger. Increasing a length of the heat exchanger to couple to a larger number of power modules can also increase a working fluid pressure drop across the heat exchanger, resulting in a larger energy demand to pump the working fluid through the heat exchanger.

In some implementations, at least one technical solution to the foregoing technical problems may include a variation in one or more design parameters of the heat exchanger across a width or length of the heat exchanger to vary operating parameters of the heat exchanger according to a number, size, or location of heat sources coupled to the heat exchanger. Example heat exchanger operating parameters may include a heat transfer rate, a temperature, and/or a fluid pressure drop. In some examples, the design parameters may include one or more of a heat sink fin height, a fin spacing, a fin cross-sectional shape, or a fin cross-sectional area. In some examples, the design parameters may include one or more of a wall thickness of a water jacket housing, a cross-sectional flow area of a water jacket interior volume, or a size of a working fluid bypass for allowing a portion of the working fluid to bypass a portion of heat sink fins.

A power device module can include at least one substrate (e.g., a power electronic substrate such as a direct bonded metal (DBM) substrate) on which circuit components and devices (e.g., insulated-gate bipolar transistor (IGBT) power devices, fast recovery diodes (FRDs), silicon carbide metal-oxide-semiconductor field-effect transistors (SiC MOSFETs), silicon (Si) MOSFETs), metal-oxide high-voltage DC line capacitors, main circuit bus bars, a power device module drive circuit board, a motor control circuit board, three-phase current sensors, and DC and heavy-current AC connectors, etc.) are attached (e.g., soldered). A power device module can be held, e.g., packaged in a casing or housing.

In some implementations, one or more semiconductor die (e.g., one or more semiconductor components) can be, or can include, a power semiconductor die. In some implementations, one or more semiconductor die can be (e.g., can be a portion of), or can include, one or more of a MOSFET device, an IGBT, an integrated circuit (IC), an inverter, a power conversion circuit, a bridge circuit, a FRD, a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

The components and devices may be attached as semiconductor dies (integrated circuit chips) on a top surface of the DBM substrate. The top surface of the DBM substrate may include metal traces and conductive pads to electrically connect the components and devices. For example, a pad on a semiconductor die of a component may be wire bonded to a metal trace on the substrate, which, in turn, may be welded to a lead frame or terminal finger providing an external connection terminal to the package. Pins (e.g., signal pins) may also be attached (e.g., soldered) to the traces on the substrate to provide external connection points to the circuit components and devices.

In some implementations, the DBM substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

The package casing (e.g., of a single-side cooling (SSC) power device module) may include a cover portion affixed (e.g., epoxied) to a base portion so that the DBM substrate and the components are contained within a cavity (an interior volume) defined by the base portion and the cover portion. The cover portion of the casing, opposite to the base portion, may include holes through which the pins (e.g., soldered signal pins) can extend to the outside of the package to provide exterior connection points to the components and circuitry contained within the casing. The package casing and its cover portion may be made of plastic or polymer materials.

In an SSC power device module, cooling may be achieved by thermal radiation from an outer surface of the DBM substrate. In a dual-side cooling (DSC) power device module, the semiconductor dies (which may be attached to spacer blocks) are disposed between two DBM substrates (e.g., a top DBM substrate and a bottom DBM substrate) in the package casing. In some example implementations, the semiconductor die (which may be attached to a spacer block) may be disposed between the bottom DBM substrate and a conductive strip of material (e.g., a copper clip, an aluminum clip, etc.). In a DSC power device module, cooling may be achieved by, and limited to, radiation emitting from the outer surfaces of the two DBM substrates (or conductive strips of material, e.g., a metal clip).

In some implementations, a heat exchanger (e.g., a base plate, a fin array, a pin-fin array, and/or a liquid cooling jacket) can help draw away, transfer, or dissipate the heat generated by the power device modules. The heat sink may be coupled to, for example, a bottom side of a DBM substrate.

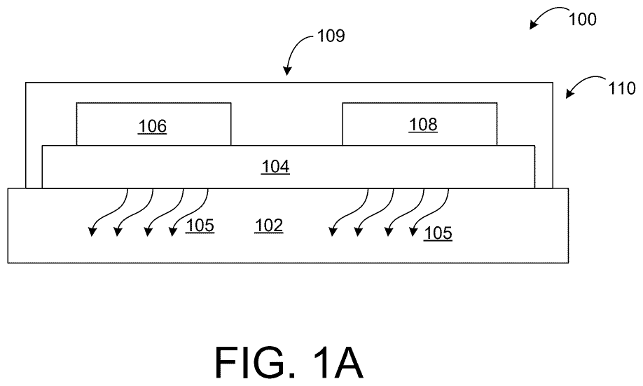

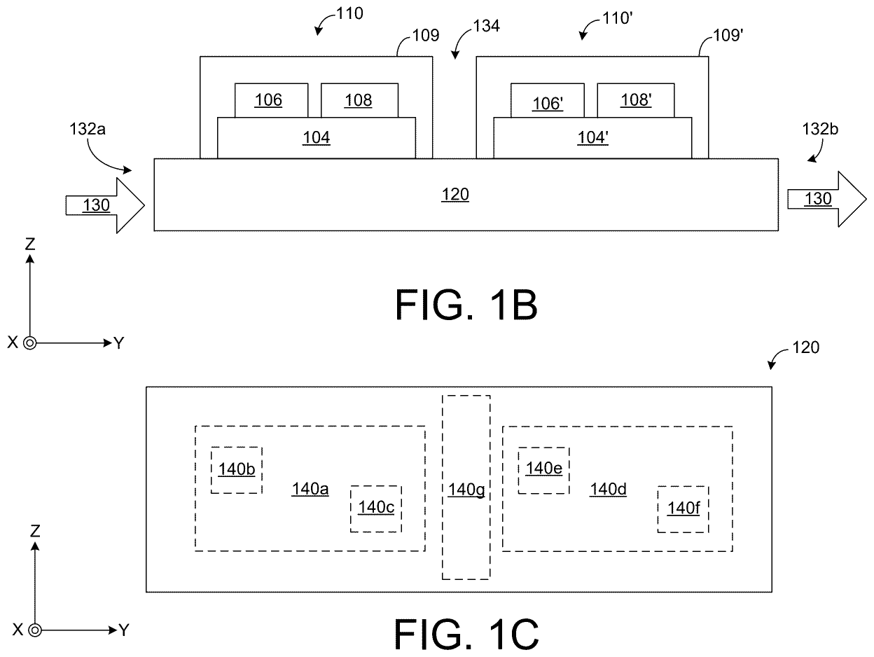

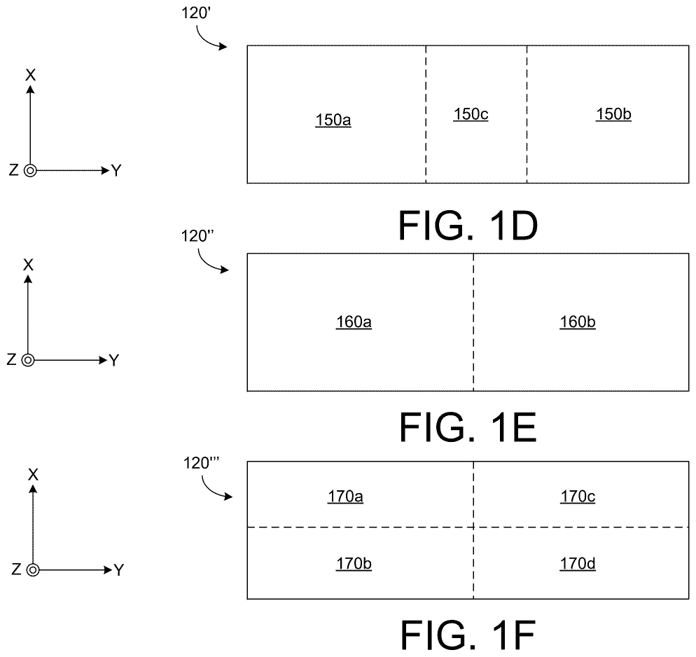

FIG. 1A is a schematic side view of an example power electronics assembly 100 which includes an SSC power device module 110 and a heat exchanger 102 coupled to a bottom side thereof for transferring or dissipating thermal energy 105 generated by the power device module 110. The power device module 110 may include a DBM substrate 104 (e.g. a direct bond copper, or DBC substrate) on which power devices (e.g., power devices 106, 108) are disposed. The DBM substrate 104 and power devices 106, 108 may be disposed in a casing 109. The power devices may be any type of power device, including any disclosed herein, such as an IGBT, MOSFET, or diode, etc. In some examples, the power device module 110 may include one or more additional layers for electrically, mechanically, and/or thermally coupling the components, such as a heat spreader (not illustrated) located, e.g., between the DBM substrate 104 and the heat exchanger 102 and/or solder layers and/or thermal grease layers.

FIG. 1B is a schematic side view of an example implementation in which two SSC power device modules, e.g., the power device module 110 and a second power device module 110′ are coupled to a heat exchanger 120, the power device module 110′ including a power device 106′ and a power device 108′ disposed on a DBM substrate 104′. The casings 109, 109′ may be spaced apart by a gap 134 where there are no semiconductor electronic devices coupled to the heat exchanger 120. In an example, one or more of the power devices 106, 108, 106′, and 108′ may have a different heat generation rate or operating temperature requirement than one or more of the other power devices. In some examples, a working fluid 130, e.g., air, water, or refrigerant, may pass across the heat exchanger 120 from a first side 132a at, e.g., a working fluid inlet or a first side of an open heat sink, to a second side 132b, e.g., a working fluid outlet or a second side of an open heat sink. In some examples, a temperature of the working fluid 130 may increase as the working fluid travels from the first side 132a to the second side 132b. The increase in temperature may result in the working fluid being less effective at transferring heat away from the power device module 110 or second power device module 110′. In an example, heat exchanger 120 is designed and configured to maintain a stable transistor junction temperature within the power devices. In an example, heat exchanger 120 may be designed and configured to maintain a stable fluid pressure of a working fluid flowing through the heat exchanger.

FIG. 1C is a top view of heat exchanger 120 with the power device modules 110, 110′ removed. As shown in FIG. 1B, the heat exchanger 120 may have one or more regions that correspond to regions of the power device modules 110. By way of example, the heat exchanger 120 may have a first region 140a, a second region 140b, and a third region 140c configured to be aligned with locations where the power device module 110, power device 106, and power device 108, respectively, will be coupled to the heat exchanger 120.

The heat exchanger may similarly include a fourth region 140d, a fifth region 140e, and a sixth region 140f configured to be aligned with a location where the power device module 110′, power device 106′, and power device 108′, respectively, will be coupled to the heat exchanger. The heat exchanger 120 may also include a seventh region 140g configured to be aligned with a location where the gap 134 between the power device modules will be located.

Heat exchanger 120 may be designed and configured to have a different performance characteristics in different regions of the heat exchanger. In some examples, the location of the regions and the performance characteristics are configured according to characteristics of heat generating components coupled to the heat exchanger and a location where the heat generating components are located on the heat exchanger. The performance characteristics of the heat exchanger that may be varied include a heat transfer rate and a fluid pressure drop. In some examples, some regions may have a higher heat transfer rate, for example, through an increased surface area of the heat transfer surfaces and/or a thermal conductivity of heat transfer elements may be increased. Some regions may have a lower heat transfer rate, for example, the region may have a bypass flowpath where a working fluid may bypass a portion of the heat transfer surfaces or elements, thereby reducing a heat transfer rate as well as a fluid pressure drop through the heat exchanger.

In the exchange shown in FIG. 1C, any of regions 140a-140g may have a different characteristic than one or more other regions of the heat exchanger. For example, power devices 106 and 106′ may generate more heat than power devices 108 and 108′. Regions 140b and 140e of the heat exchanger may be configured to be more effective at dissipating heat than regions 140c and 140f. Region 140g may be configured to have a lower heat transfer rate and a lower pressure drop due to the lack of heat generation in that region. In an example, region 140d may have a different characteristic than region 140a to account for a higher working fluid temperature in that region. In an example a surface area of eat transfer surfaces may be increased or a size of one or more bypass flowpaths may be decreased in region 140d as compared to region 140a.

As will be appreciated, the example shown in FIG. 1C is provided by way of example only and any number regions, size of regions, and shapes of regions of a heat exchanger of the present disclosure may be used. In some examples a number, size, and location of the regions may be designed and configured according to the characteristics of heat-generating components coupled to the heat exchanger, including a size, heat generation rate, and/or location of the heat generating components, and the like.

FIGS. 1D-1F are top side views of examples of heat exchangers that are configured to be coupled to the two power device modules 110, 110′ in the manner shown in FIG. 1B. In the illustrated examples, a heat exchanger 120′ (FIG. 1D) includes regions 150a-105c that are positioned in a flow direction along the heat exchanger, where regions 150a and 150b are configured to be aligned with a location of power device modules 110, 110′ and region 150c is configured to be aligned with the gap 134. Regions 150a-150c extend across a width of the heat exchanger in a direction perpendicular to the flow direction.

A heat exchanger 120″ (FIG. 1E) includes two regions 160a, 160b that are positioned in a flow direction along the heat exchanger, where regions 160a and 160b are configured to be aligned with power device modules 110, 110′. Regions 150a and 150b extend across a width of the heat exchanger in a direction perpendicular to the flow direction.

A heat exchanger 120′″ (FIG. 1F) includes four regions including first and second regions 170a, 170b that are configured to be aligned power device module 110 and third and fourth regions 170c, 170d configured to be aligned with power device module 110′. Heat exchanger 120′″ includes regions that vary in a width direction of the heat exchanger, where regions 170a, 170b, 170c, and/or 170d may not extend across an entire width of a flow area of the heat exchanger 120′″.

In other examples that include a different number of heat generating components the regions of the heat exchanger may vary. For example, in an example that includes three or more power device modules, such as power device module 110, the heat exchanger may have a corresponding number of regions, where the number of regions is equal to or greater than the number of power device modules. For example, a heat exchanger may have three or more power device modules coupled to the heat exchanger along a flow direction of the heat exchanger and the heat exchanger may include two or more regions for varying a characteristic along a length of the heat exchanger.

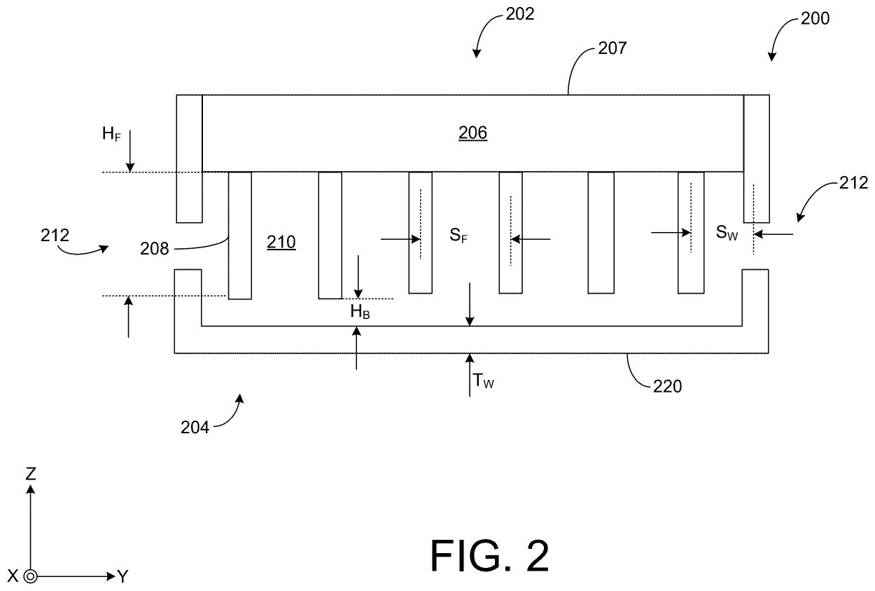

FIG. 2 is a schematic cross-sectional side view of an example heat exchanger 200 which, in an example, may be coupled to a power device module such as power device module 110. Heat exchanger 200 is a liquid cooling jacket heat exchanger and includes a heat sink 202 and a housing 204. Heat sink 202 includes a baseplate 206 and a plurality of fins 208 (only one labeled) extending from a bottom side of the base plate. In an example, a top side 207 of the baseplate 206 may be coupled to a bottom side of a DBM substrate such as DBM substrate 104. The housing 204 and heat sink 202 define an interior volume 210 that is designed to contain a working fluid such as water or a refrigerant. Housing 204 includes fluid ports 212 for transfer of a working fluid into and out of the heat exchanger 200. In an example, heat exchanger 200 may be coupled at the fluid ports 212 to a fluid circuit. The fluid circuit may include fluid conduits and at least one pump (not illustrated) for the pumping of the working fluid as part of a cooling circuit for the transfer of heat from a power device module for maintaining the power device module below allowable temperature limits during operation. The working fluid may generally flow in a direction parallel to the Y axis, also referred to herein as a flow direction, and perpendicular to the X axis.

Heat exchanger 200 includes a number of design parameters that may be optimized for a given application. For example, design parameters may include, a fin height, h_{F}, a bottom bypass height, h_{B}, a fin spacing, S_{F}, and a fin to wall spacing, S_{W}. Design parameters may also include a cross-sectional flow area of the interior volume 210, which may vary along a length or width of the heat exchanger 200. Design parameters may also include a thickness, t_{W}, of a wall 220 of the housing 204, which may vary along a length or width of the heat exchanger 200. Design parameters may also include a cross-sectional shape of the fins, a cross sectional area or size of the fins, and a thermal conductivity of the fins. Design parameters may also include a thermal conductivity of the baseplate 206, which may vary in a width or length direction of the heat exchanger. Design parameters such as the foregoing design parameters may be varied to vary performance characteristics such as a heat transfer rate and working fluid pressure drop. For example, in certain regions of the heat exchanger, a spacing can be increased to decrease a fluid pressure drop, thereby reducing power requirements for the cooling system. By contrast, in higher heat flux areas, a heat transfer area or thermal conductivity may be increased through, for example, material selection or geometry, to achieve desired thermal performance.

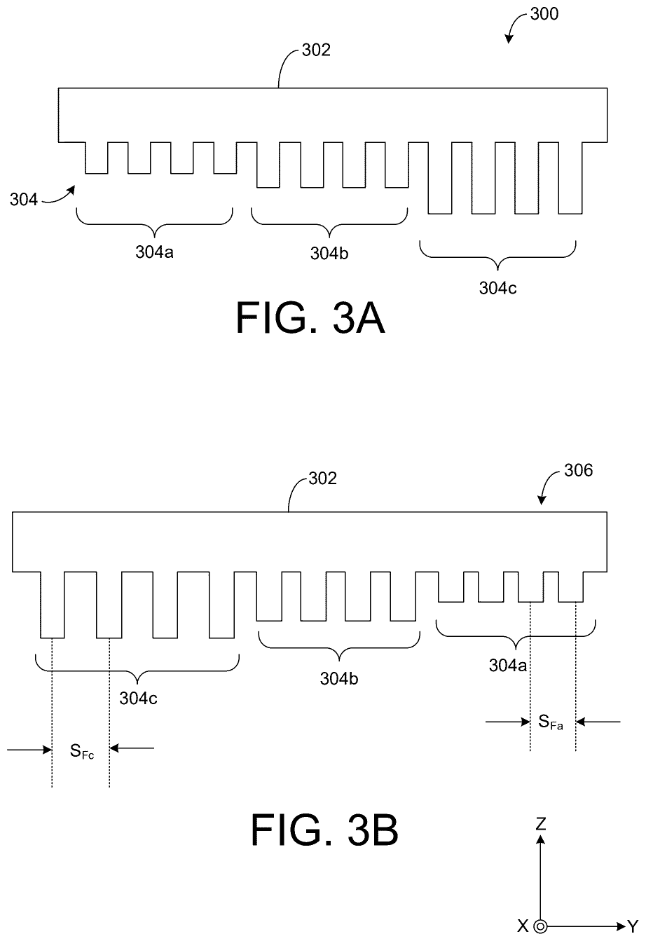

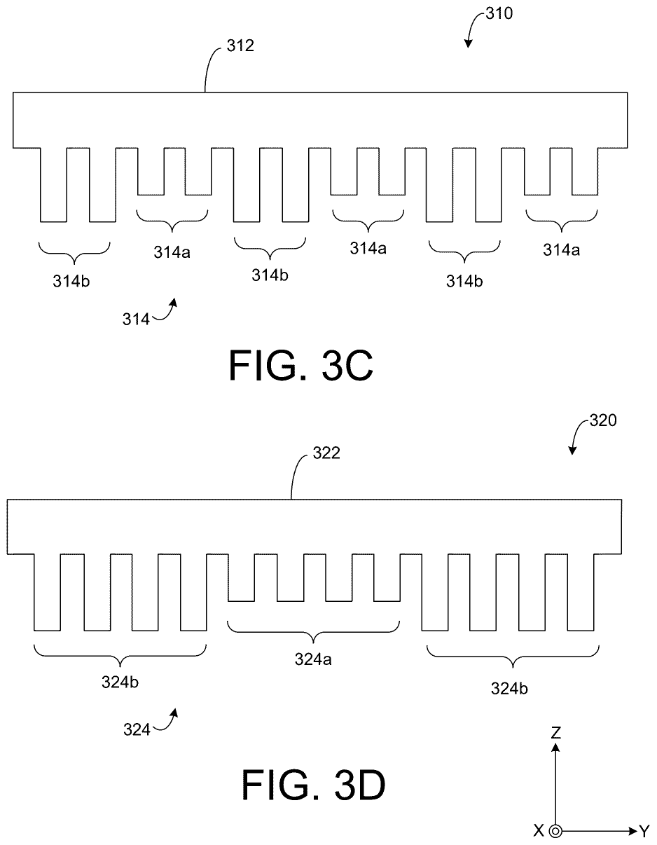

FIGS. 3A-3D illustrate example implementations of heat sinks where the fin height, hf, is varied along a length or flow direction of the heat sink. In other examples, the fin height may vary in the width direction. FIGS. 3A-3D are side views of the example heat sinks in the Y-Z plane. FIG. 3A shows an example heat sink 300, which includes a baseplate 302 and a plurality of fins 304 extending from a bottom side of the baseplate. The fins 304 include a first portion 304a having a first height, a second portion 304b having a second height, and a third portion 304c having a third height, wherein the third height is greater than the second height and the second height is greater than the first height. A height of the fins 304 varies along a length or width of the heat sink 300 and in the illustrated example, form three discrete regions (first portion 304a/second portion 304b/third portion 304c), with a constant height in the Y-Z plane within the region. The fin height in a given region in the width direction (X direction) may be constant, or it may vary. In an example, first portion 304a may be located in a region requiring lower heat transfer, second portion 304b may be located in a region requiring an intermediate level of heat transfer, and third portion 304c may be located in a region requiring a higher level of heat transfer. The regions, e.g., first portion 304a, second portion 304b, and third portion 304c are examples of the regions described above in connection with FIGS. 1C-1F, where regions, e.g., first portion 304a, second portion 304b, and third portion 304c, are selected according to the characteristics of heat generating components coupled to the heat exchanger.

FIG. 3B shows an example heat sink 306 that is substantially the same as heat sink 300, including the baseplate 302 and the first portion 304a, second portion 304b, and third portion 304c of fins 304 forming three distinct regions of the heat sink. Heat sink 306 differs from heat sink 300 in the locations of the three portions of fins 304 with a decreasing height in the Y direction rather than an increasing height. Heat sink 306 also differs from heat sink 300 in that a spacing, S_{F} of the fins 304 may vary along the length or width of the heat exchanger. In the illustrated example a spacing S_{Fc} of the third portion 304c of the fins 304 is greater than a spacing S_{Fa} of the first portion 304a of the fins. An increased spacing may result in a lower heat transfer rate as well as a lower working fluid pressure drop in the third portion 304c of the fins.

FIG. 3C shows an example heat sink 310, which includes a baseplate 312 and a plurality of fins 314 extending from a bottom side of the baseplate. The fins 314 include a first portion 314a having a first height and a second portion 314b having a second height, wherein the second height is greater than the first height. A height of the fins 314 varies along a length or width of the heat sink 310 and in the illustrated example, form alternating discrete regions of high and low pins with constant height in the Y-Z plane within a region. The fin height in a given region in the orthogonal X-Z plane may be constant, or it may vary. In an example, first portions 314a may be located in regions requiring lower heat transfer, and second portions 314b may be located in regions requiring higher heat transfer.

FIG. 3D shows an example heat sink 320, which includes a baseplate 322 and a plurality of fins 324 extending from a bottom side of the baseplate. The fins 324 include a first portion 324a having a first height and a second portion 324b having a second height, wherein the second height is greater than the first height. A height of the fins 324 varies along a length or width of the heat sink 320 and in the illustrated example, form alternating discrete regions of high and low pins with constant height in the Y-Z plane within a region. The fin height in a given region in the orthogonal X-Z plane (width or X direction) may be constant, or it may vary. In an example, first portions 324a may be located in regions requiring lower heat transfer, and second portions 324b may be located in regions requiring higher heat transfer.

FIGS. 3A-3D illustrate examples where the fins of a heat sink are non-uniform across a width or length of the heat sink, for example, a length, a fin-to-fin gap or spacing, a fin cross sectional shape or size, or a thermal conductivity of the fins may be non-uniform or vary across a length or width of the heat sink. In some examples, the fins are arranged in a pattern in accordance with the fin height.

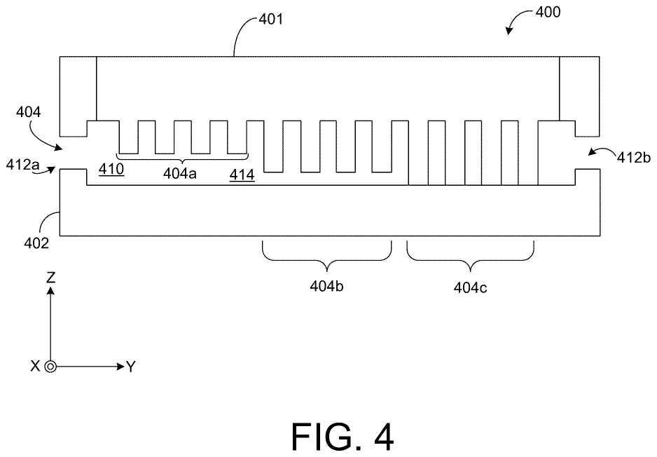

FIG. 4 is a side view of an example heat exchanger 400 in the form of a liquid cooling jacket heat exchanger that includes a heat sink 401 coupled to a housing 402 to define an interior volume 410 that is designed to contain a working fluid such as water or a refrigerant. Housing 402 includes fluid ports 412a, 412b for the transfer of the working fluid into and out of the heat exchanger 400. In the illustrated example, heat sink 401 includes a plurality of fins 404 that include portions of fins with varying heights. In the illustrated example the fins 404 are similar to the fins 304 of heat sink 300 and include a first portion 404a having a first height, a second portion 404b having a second height, and a third portion 404c having a third height, wherein the third height is greater than the second height and the second height is greater than the first height. In the illustrated example the height of the fins 404 varies in a flow direction of the heat exchanger, e.g., generally in a flow direction of the working fluid between the fluid ports 412a, 412b. The height in the orthogonal direction (X direction) may be constant or may vary.

In other examples, alternate fin height configurations such as fin height configurations similar to heat sinks 306, 310, or 320 (FIGS. 3A-3D) may be used. A cross-sectional flow area of the interior volume 410 may be greater in the region with the first portion 404a of fins 404 as compared to the region with the third portion 404c due to the lower cross sectional area taken up by the shorter fins. The shorter length of the first portion 404a of the fins 404 results in a bottom bypass flowpath 414 that is defined between the ends, or bottom ends, of the first portion 404a of the fins 404 and an interior wall of the housing 402. The bottom bypass flowpath 414 may result in a lower working fluid pressure drop through the region containing the first portion of fins. By contrast, the longer length of the second portion 404b and third portion 404c of the fins 304 may result in both a higher heat transfer rate as well as a greater pressure drop. Third portion 404c has a height that is the same as a height of the interior volume 410, resulting in no bottom bypass flowpath in the region containing the third portion 404c of the fins 404. For example, the third portion 404c may be in a region of the heat exchanger 400 that does not include a bypass flowpath also referred to as a bypass.

In an example, a power device module, such as power device module 110 may be mounted on the heat exchanger 400 and may include a first portion aligned with a first region of the heat exchanger 400 that has a first heat generation and a second portion aligned with a second region of the heat exchanger 400 that has a second heat generation that is different than the first heat generation. The heat exchanger 400 may include a bypass that allows a portion of a working fluid to bypass one or more of the plurality of fins where the bypass including a first portion in the first region that has a first size, for example, first portion 404a, and a second portion in the second region that has a second size that is different than the first size, for example, second portion 404b. The heat exchanger 400 may also include a third region that does not include a bypass, for example the region that contains third portion 404c of the fins 404. In the illustrated example, the third region is located downstream in a fluid flow direction of the first region and the second region. In an example, the third region is located between the first region and the second region, for example, the third portion 404c may be located between the first portion 404a and the second portion 404b.

In an example, a first power device module, such as the power device module 110 and a second power device module, such as the power device module 110′ (FIG. 1), may be mounted to a heat exchanger, such as the heat exchanger 400. A second region of the heat exchanger 400 that is aligned with a space between the casing 109 of the power device module 110 and the casing 109′ of the power device module 110′ may have a different configuration than a first region of the heat exchanger 400 aligned with the power device module 110 and/or power device module 110′. For example, the second region of the heat exchanger may include a bypass that allows a portion of a working fluid to bypass one or more of the plurality of fins, such as first portion 404a or second portion 404b. In an example, the first region of the heat exchanger that is aligned with the power device module 110 and/or power device module 110′ may not include a bypass, such as the third portion 404c. In some examples, the first region may include a bypass and the second region may not include a bypass. In some examples, both the first and second region may include a bypass that may have substantially the same configuration or that may have a different configuration, for example, a different size, for example, a different height or width.

In an example, fluid port 412a may be an inlet fluid port and fluid port 412b may be an outlet fluid port. A temperature of the working fluid may be greater at outlet fluid port 412b than inlet fluid port 412a. The higher temperature of the working fluid may reduce the effectiveness of the working fluid to transfer heat in the downstream regions of the heat exchanger. The height of the fins 404, may, therefore, increase is a flow direction to counteract the reduced heat transfer due to the higher temperature of the working fluid, resulting in a more consistent heat transfer rate along a length of the heat exchanger.

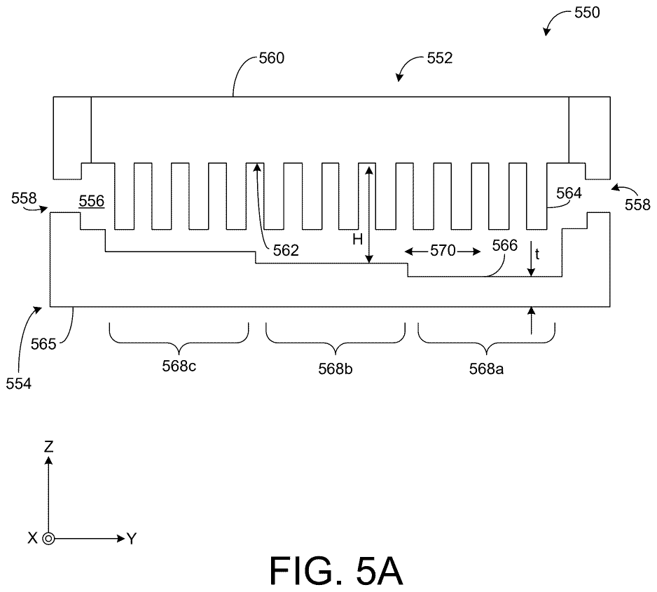

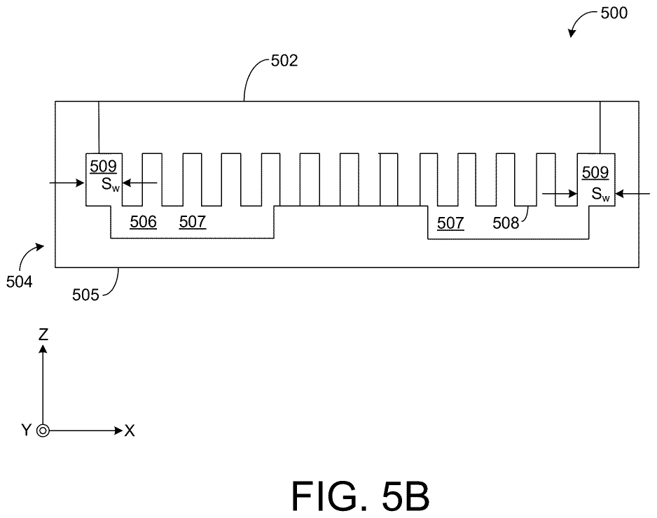

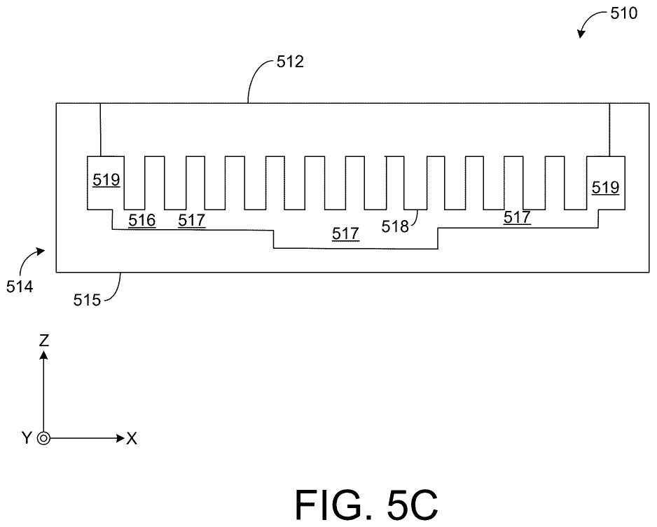

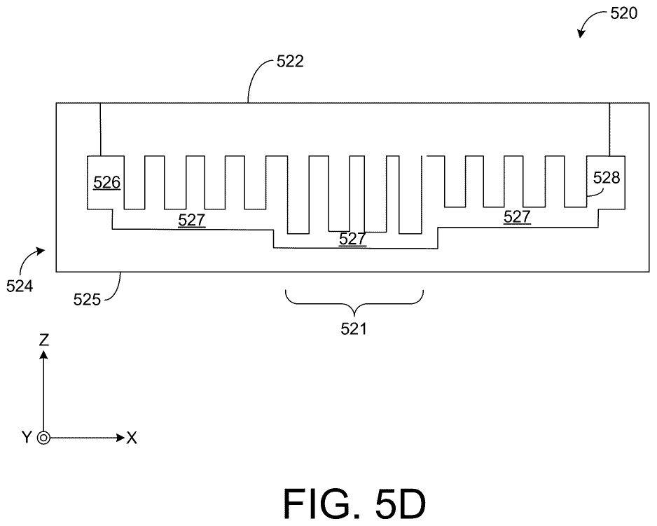

FIG. 5A is a cross-sectional side view in the Y-Z plane and FIGS. 5B-5D are cross-sectional side views in a X-Z plane. FIGS. 5A-5D illustrate example heat exchangers with a varying wall thickness of a housing of the heat exchanger. In the examples illustrated in FIGS. 5A-5C, a height of the heat sink fins is constant. The varying wall thickness of the housing results in varying sizes of a bottom bypass flowpath. In the example shown in FIG. 5D, a height of the fins may also vary along a width or length of the heat exchanger.

FIG. 5A is a side cross-sectional view of an example heat exchanger 550 in the form of a liquid cooling jacket heat exchanger. Heat exchanger 550 includes a heat sink 552 coupled to a housing 554 which together define an interior volume 556 that is designed to contain a working fluid such as water or a refrigerant. Housing 554 includes fluid ports 558 for transfer of the working fluid into and out of the heat exchanger. In the example shown in FIG. 5A, a flow area of the interior volume 556 may be varied in either a first or second direction, e.g., the X and/or Y direction, by varying a height, H, of the flow passage defined by the interior surfaces of the baseplate and housing. FIG. 5A is a cross-sectional view in the Y-Z plane and shows a flow area that varies in a flow direction between, i.e., in the Y direction, extending between the two fluid ports 558.

Heat sink 552 may include a baseplate 560 with an interior surface 562 and a plurality of fins 564 extending therefrom and the housing 554 may include a wall 565 with an interior surface 566 that faces the interior surface 562 of the baseplate, the interior surfaces 562, 566 define a height, H, of a flow passage of the heat exchanger 550. In the example of FIG. 5A, a thickness, t, of the wall 565 of housing 554 varies along a length of the housing, resulting in a varying interior surface 566 of the housing. In the illustrated example interior surface 566 is a stepped surface, resulting in a varying height, H, of the flow passage and corresponding variation in a cross-sectional area of the flow passage.

In the illustrated example, wall 565 of housing 554 includes a first portion 568a having a first thickness, a second portion 568b having a second thickness, and a third portion 568c having a third thickness, wherein the third thickness is greater than the second thickness and the second thickness is greater than the first thickness. Portions 568a-568c define three distinct regions of the heat exchanger 550. In an example, a height of the fins 564 is constant along a length of the heat exchanger in the same Y-Z plane, e.g., the flow direction. Thus, the varying thickness of the wall 565 results in a variation in a height of a bottom bypass 570, where the bottom bypass is a flowpath where the working fluid can bypass the fins 564. The bottom bypass 570 represents a lower-resistance flowpath than the tortuous flowpath through the fins 564, which may result in a lower pressure drop across the heat exchanger. Allowing flow to bypass the fins 564 may also reduce a heat transfer rate from the fins adjacent the bottom bypass due to the reduced volumetric flow rate of the working fluid through the fins.

In the illustrated example the housing 554 has three discrete regions defined by portions 568a, 568b, and 568c, with a constant flow passage height, H, in the flow direction within a given region. The thickness, t, of wall 565 and the corresponding flow passage height, H, resulting from the wall thickness in a given region in the X-Z plane (a width direction, or a direction orthogonal to the flow direction) may be constant, or it may vary. In an example, first portion 568a may be located in a region requiring lower heat transfer as compared to other regions in the illustrated Y-Z plane of the heat exchanger. For example, portion 568a has a reduced thickness of wall 565 resulting in a larger bottom bypass 570, which may reduce a heat transfer from fins 564 adjacent the first portion 568a but also reduce a pressure drop through that region. Second portion 568b may be located in a region requiring an intermediate level of heat transfer, and therefore have a reduced bottom bypass 570 as compared to first portion 568a which may increase a heat transfer rate from fins proximate second portion 568b due to an increased fluid flow through the fins. Third portion 568c may be located in a region requiring a higher level of heat transfer as compared to second portion 568b and have a corresponding reduced bottom bypass 570 as compared to second portion 568b which may increase a heat transfer rate from pins proximate first portion 568a due to an increased fluid flow through the fins. The foregoing description is provided by way of example and other variations and applications may be applied. For example, in one implementation, a design heat transfer rate may be similar for two of the portions 568a-568c or all three portions 568a-568c. The reduction in the bottom bypass 570 and increase in flow through the fins 564 may be designed to maintain a similar heat transfer rate through each portion despite an increase in working fluid temperature through the heat exchanger.

FIG. 5B shows an example heat exchanger 500 in the form of a liquid cooling jacket heat exchanger that includes a heat sink 502 coupled to a housing 504. The heat sink 502 and housing 504 define an interior volume 506 that is designed to contain a working fluid such as water or a refrigerant. Heat sink 502 includes a plurality of fins 508. FIG. 5C shows an example heat exchanger 510 in the form of a liquid cooling jacket heat exchanger that includes a heat sink 512 coupled to a housing 514. The heat sink 512 and housing 514 define an interior volume 516 that is designed to contain a working fluid such as water or a refrigerant. Heat sink 512 includes a plurality of fins 518.

Heat exchangers 500 (FIG. 5B) and 510 (FIG. 5C) are similar to heat exchanger 550 (FIG. 5A), wherein the fins 508, 518 have a constant height and a thickness of a wall 505, 515 of the housing 504, 514 varies in a width or length direction, resulting in a varying cross sectional flow area and bottom bypass flow area. In example heat exchanger 550 (FIG. 5A), the illustrated variation in the thickness of wall 565 is in a direction that is parallel to a working fluid flow direction, e.g., a flow direction. Example heat exchangers 500 and 510 (FIGS. 5B, 5C), by contrast, have a variation in the thickness of the wall 505, 515, is in a direction that is perpendicular to a working fluid flow direction, here the X direction, that results in one or more bottom bypass flowpaths 507, 517. In other examples, a heat exchanger may have the same or similar variation in wall thickness and flow passage height in another direction, e.g., a direction orthogonal to the illustrated direction. Example heat exchangers 500 and 510 may also have a fin-to-side-wall spacing, S_{W}, (FIG. 5B) that defines a side bypass flowpath 509, 519 that allows the working fluid to bypass the plurality of fins 508 or 518 along a side of the fins in addition to or instead of the bottom of the fins along the bottom bypass flowpath(s) 507, 517. For example, the side bypass flowpath 509, 519 may extend in a direction transverse to a longitudinal axis of one of the fins 508 or fins 518 between the fin and the wall of the housing. In an example, the fin-to-side-wall spacing, S_{W}, may be greater than as fin-to-fin spacing between one or more of the plurality of fins 508 or plurality of fins 518. For example, a width of the side bypass flowpath 509, also referred to as a side bypass, may be greater than a spacing between adjacent ones of the plurality of fins. The width or height of the side bypass flowpath 509 or side bypass flowpath 519 may vary along a length of the heat exchangers 500. For example, the side bypass flowpath 509 or side bypass flowpath 519 in a first region of the heat exchanger 500 or heat exchanger 510 may be defined at least in part by a first portion of a wall of the housing 504, 514 and a first fin of the plurality of fins 508, 518 and a side bypass flowpath 509, 519 a second region of the heat exchanger 500 may be defined at least in part by a second portion of the wall of the housing 504, 514 and a second fin of the plurality of fins 508, 518. In an example, a shape or a thickness of the first fin or the first portion of the wall may be different than a shape or a thickness of the second fin or the second portion of the wall, which may at least in part provide the change in dimension of the side bypass flowpath 509, 519 between the first portion and the second portion of the heat exchanger 500 or heat exchanger 510.

FIG. 5D shows an example heat exchanger 520 in the form of a liquid cooling jacket heat exchanger that includes a heat sink 522 coupled to a housing 524 to define an interior volume 526 that is designed to contain a working fluid such as water or a refrigerant. Heat sink 522 includes a plurality of fins 528. The housing 524 of example heat exchanger 520 is similar to housing 514 of heat exchanger 510, with a wall 525 having a varying thickness. Unlike heat exchanger 510, the plurality of fins 528 of heat exchanger 520 have a height that varies along a width or depth of the heat exchanger. In the illustrated example, a wall 525 of housing 524 has a reduced thickness in a first region 521. The plurality of fins 528 have an increased height in the first region 521 resulting in a height of a bottom bypass flowpath 527 being substantially constant across the width of the heat exchanger in the X direction. Thus, as shown in FIG. 5D, a height of the fins of a heat sink and a thickness of a wall of a housing can both be varied in a given heat exchanger.

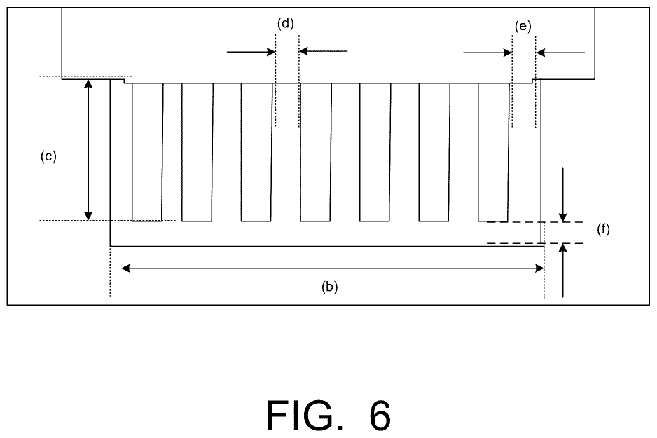

Table 1 is a table of computational fluid dynamics (CFD) calculations for eight different heat exchanger configurations and FIG. 6 is a schematic of a heat exchanger that corresponds to Table 1. The data in Table 1 was generated from CFD calculations with a flow rate of 10 liter/min, a flow velocity at inlet of 0.6159 m/s and an inlet area after meshing of 2.706E-4.

In the eight example heat exchanger configurations shown in Table 1, a bottom bypass (f), a side bypass (e), a fin height (c), and a fin-to-fin gap (d) are varied. Table 1 shows how the calculated pressure drop varies for the different configurations where larger bypasses and fin-to-fin gaps have lower corresponding pressure drops illustrating how the heat exchanger design parameters disclosed herein may be varied to affect a fluid pressure drop in the heat exchanger.

TABLE 1

| | ID | | | | | | | |
|---|---|---|---|---|---|---|---|---|
| | | | (c) Fin | (d) Fin | | (f) Bottom | | |
| | (a)Fin, (b)shape | (b) Chan. | height | to fin | (e) Fin to | Bypass | Pressure drop (mbar) | |
| | (mm) | Width (mm) | (mm) | gap (mm) | wall (mm) | (mm) | @65° C. | @55° C. |
| 7.7 h | Oval (3.0 × 1.5) | 23.3 | 7.7 | 1.3 | 1.1 | 0 | 222 | 240 |
| 7.7 h + 1.1 BP | Oval (3.0 × 1.5) | 23.3 | 7.7 | 1.3 | 1.1 | 1.1 | 155 | 160 |
| 9.0 h | Oval (3.0 × 1.5) | 23.3 | 9 | 1.3 | 1.1 | 0 | 185 | 195 |
| 9.0 h + 1.1 BP | Oval (3.0 × 1.5) | 23.3 | 9 | 1.3 | 1.1 | 1.1 | 134 | 142 |
| Wider + 1.5 g | Oval (3.0 × 1.5) | 29.2 | 10 | 1.5 | 1.1 | 0 | 113 | 119 |
| 1.3 g/9.0 h/1.3 sbp | Oval (3.0 × 1.5) | 29.3 | 9 | 1.3 | 1.3 | 0 | 129 | 134 |
| 1.3 g/9.0 h/1.2 sbp | Oval (3.0 × 1.5) | 29.1 | 9 | 1.3 | 1.2 | 0 | 134 | 140 |
| 1.2 g/9.0 h/1.3 sbp | Oval (3.0 × 1.5) | 29.75 | 9 | 1.2 | 1.3 | 0 | 140 | 148 |

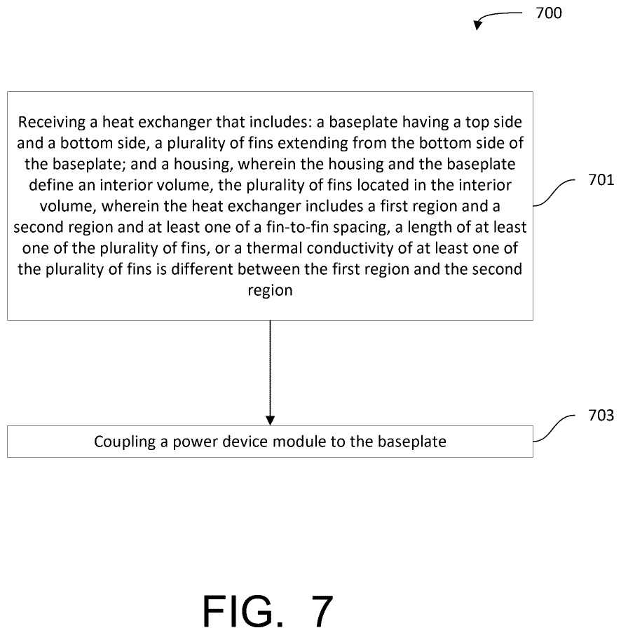

FIG. 7 is a flowchart illustrating an example method 700 of manufacturing a power electronics assembly, such as any of the power electronics assemblies disclosed herein, such as example power electronics assembly 100. Example method 700 may include, at block 701, receiving a heat exchanger that may include a baseplate having a top side and a bottom side, a plurality of fins extending from the bottom side of the baseplate, and a housing, the housing and the baseplate defining an interior volume. In an example, the plurality of fins may be located in the interior volume and the heat exchanger may include a first region and a second region. In an example, at least one of a fin-to-fin spacing, a length of at least one of the plurality of fins, or a thermal conductivity of at least one of the plurality of fins is different between the first region and the second region. The method 700 may include receiving any of the heat exchangers disclosed herein, for example, one or more of example heat exchanger 120, heat exchanger 120′, heat exchanger 120″, heat exchanger 200, heat exchanger 400, heat exchanger 500, heat exchanger 510, heat exchanger 520, and/or heat exchanger 550 or any combination of the foregoing heat exchangers.

The example method 700 may include, at block 703, coupling a power device module to the baseplate of the heat exchanger. The method 700 may include coupling any of the power device modules disclosed herein, for example, one or more of example power device module 110 and/or power device module 110′. The power device module may be coupled to the baseplate using any of the methods disclosed herein. For example, in some implementations, the power device module may include a DBM substrate that can include an insulating layer disposed between a first metal layer and a second metal layer. In some implementations, the first metal layer and/or the second metal layer of the DBM substrate can be or can function as a heat sink. In some implementations, the first metal layer and/or the second metal layer can be coupled to the heat exchanger. In some implementations, at least a portion of one or more of the first metal layer or the second metal layer can be exposed through a molding material.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Carbide (SiC), Gallium Arsenide (GaAs), Gallium Nitride (GaN), and/or so forth.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, a spacer material can be an epoxy, a silicone adhesive, a conductive material, a non-conductive material, an organic material, a semiconductor material, a metal alloy, a metal foam, a phase change material, etc.

While certain features of the described implementations have been illustrated as described herein, many modifications, substitutions, changes and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A power electronics assembly, comprising:
a power device module; and
a heat exchanger that includes:
a baseplate having a top side and a bottom side;
a plurality of fins extending from the bottom side of the baseplate; and
a housing, the housing and the baseplate defining an interior volume and the plurality of fins located in the interior volume;
wherein the heat exchanger includes a bypass that allows a portion of a working fluid to bypass one or more of the plurality of fins.

2. The power electronics assembly of claim 1, wherein the bypass is a bottom bypass extending between a bottom end of at least one of the plurality of fins and a wall of the housing.

3. The power electronics assembly of claim 2, wherein the bottom bypass includes:
a first height in a first region of the heat exchanger extending between a first fin of the plurality of fins and a first portion of the wall; and
a second height in a second region of the heat exchanger extending between a second fin of the plurality of fins and a second portion of the wall;
wherein the first height is different than the second height.

4. The power electronics assembly of claim 3, wherein a length of the first fin is different than a length of the second fin.

5. The power electronics assembly of claim 3, wherein a thickness of the first portion of the wall is different than a thickness of the second portion of the wall.

6. The power electronics assembly of claim 1, wherein the bypass is a side bypass extending in a direction transverse to a longitudinal axis of a first fin of the plurality of fins between a side of the first fin and a wall of the housing.

7. The power electronics assembly of claim 6, wherein a width of the side bypass is greater than a spacing between adjacent ones of the plurality of fins.

8. The power electronics assembly of any of claim 6, wherein a size of the side bypass is different between a first region of the heat exchanger and a second region of the heat exchanger.

9. The power electronics assembly of any of claim 8, wherein the side bypass in the first region is defined at least in part by a first portion of the wall of the housing and the first fin and the side bypass in the second region is defined at least in part by a second portion of the wall and a second fin of the plurality of fins, wherein a shape or a thickness of the first fin or the first portion of the wall is different than a shape or a thickness of the second fin or the second portion of the wall.

10. The power electronics assembly of any of claim 1, wherein the bypass includes a first portion having a first size and a second portion having a second size that is different than the first size.

11. A power electronics assembly, comprising:
a power device module; and
a heat exchanger that includes:
a baseplate having a top side and a bottom side;
a plurality of fins extending from the bottom side of the baseplate; and
a housing, wherein the housing and the baseplate define an interior volume, the plurality of fins located in the interior volume;
wherein the heat exchanger includes a first region and a second region and at least one of a fin-to-fin spacing, a length of at least one of the plurality of fins, or a thermal conductivity of at least one of the plurality of fins is different between the first region and the second region.

12. The power electronics assembly of claim 11, wherein the power device module includes a first portion aligned with the first region of the heat exchanger that has a first heat generation and a second portion aligned with the second region of the heat exchanger that has a second heat generation that is different than the first heat generation.

13. The power electronics assembly of claim 12, wherein the heat exchanger includes a bypass that allows a portion of a working fluid to bypass one or more of the plurality of fins, the bypass including a first portion in the first region that has a first size and a second portion in the second region that has a second size that is different than the first size.

14. The power electronics assembly of claim 13, wherein the first portion of the bypass extends between a first fin of the plurality of fins and a first portion of a wall of the housing and the second portion of the bypass extends between a second fin of the plurality of fins and a second portion of the wall of the housing, wherein a length of the first fin is different than a length of the second fin or a thickness of the first portion of the wall is different than a thickness of the second portion of the wall.

15. The power electronics assembly of claim 14, wherein the bypass is a bottom bypass extending between bottom ends of the plurality of fins and the wall of the housing, wherein the heat exchanger includes a third region that does not include a bypass.

16. The power electronics assembly of claim 15, wherein the third region is located downstream in a fluid flow direction of the first region and the second region.

17. The power electronics assembly of claim 16, wherein the third region is located between the first region and the second region.

18. The power electronics assembly of claim 11, wherein the power device module is a first power device module disposed in a first casing, the power electronics assembly further comprising a second power device module disposed in a second casing, wherein the first power device module and the second power device module are aligned with the first region and the second region is aligned with a space between the first casing and the second casing.

19. The power electronics assembly of claim 18, wherein the second region of the heat exchanger includes a bypass that allows a portion of a working fluid to bypass one or more of the plurality of fins.

20. The power electronics assembly of claim 19, wherein the first region of the heat exchanger does not include a bypass.

21. A method of manufacturing a power electronics assembly, the method comprising:
receiving a heat exchanger that includes:
a baseplate having a top side and a bottom side;
a plurality of fins extending from the bottom side of the baseplate; and
a housing, wherein the housing and the baseplate define an interior volume, the plurality of fins located in the interior volume;
wherein the heat exchanger includes a first region and a second region and at least one of a fin-to-fin spacing, a length of at least one of the plurality of fins, or a thermal conductivity of at least one of the plurality of fins is different between the first region and the second region; and
coupling a power device module to the baseplate.

22. The method of claim 21, further comprising aligning a first portion of the power device module that has a first heat generation rate with the first region of the heat exchanger and a second portion of the power device module that has a second heat generation rate that is different than the first heat generation rate with the second region of the heat exchanger.
